(19) United States
(12) Patent Application Publication
(10) Pub. No.: US 2023/0187274 A1
(43) Pub. Date: Jun. 15, 2023

(54) DIELECTRIC PLANARIZATION USING A METAL OVERBURDEN WITH ETCH-STOP LAYERS

(71) Applicant: International Business Machines Corporation, Armonk, NY (US)

(72) Inventors: Raghuveer Reddy Patlolla, Guilderland, NY (US); Donald Francis Canaperi, Bridgewater, CT (US); Cornelius Brown Peethala, Slingerlands, NY (US); Chih-Chao Yang, Glenmont, NY (US)

(21) Appl. No.: 17/551,541

(22) Filed: Dec. 15, 2021

(51) Int. Cl. H01L 21/768; H01L 23/522

(52) U.S. Cl. CPC H01L 21/76831; H01L 23/5226; H01L 21/7684

(57) ABSTRACT

Embodiments of the invention include a method of forming portions of a multi-layer integrated circuit (IC) structure. The method includes forming a back-end-of-line (BEOL) layer having a BEOL layer topography. An etch-stop layer is formed over the BEOL layer topography. A metal is formed over the etch-stop layer. A first planarization operation is applied to remove a first portion of the metal. The etch-stop layer is used to stop the first planarization operation. A second planarization operation is applied to remove the etch-stop layer and a second portion of the metal.

### BACKGROUND

The present invention generally relates to fabrication methods and resulting structures for integrated circuit wafers. More specifically, the present invention relates to fabrication methods and resulting dielectric layers that are planarized using a metal overburden and an etch-stop layer, which, in some embodiments of the invention, can include a liner layer, a barrier layer, or a combined liner/barrier layer.

Integrated circuits (ICs) are fabricated in a series of stages, including a front-end-of-line (FEOL) stage, a middle-of-line (MOL) stage and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts and other structures that communicatively couple to active regions (e.g., gate, source, and drain) of the device element. The BEOL layers use insulating and stabilizing dielectric materials embedded with a network of wires, lines and vias that couple current to FEOL and MOL layers to complete the IC. The BEOL layers can also include embedded MRAM formed from memory structures such as MTJ stacks. Most ICs need more than one layer of wires/lines to form all the necessary connections, and as many as 5-12 layers are added in the BEOL process.

The increasing number of BEOL layers requires a highly planarized surface on every layer. Excessive material is removed and layer surfaces are planarized by the application of a suitable planarization processes such as chemical-mechanical planarization (CMP).

### SUMMARY

Embodiments of the invention include a method of forming portions of a multi-layer integrated circuit (IC) structure. The method includes forming a back-end-of-line (BEOL) layer having a BEOL layer topography. An etch-stop layer is formed over the BEOL layer topography. A metal is formed over the etch-stop layer. A first planarization operation is applied to remove a first portion of the metal. The etch-stop layer is used to stop the first planarization operation. A second planarization operation is applied to remove the etch-stop layer and a second portion of the metal.

Embodiments of the invention include a method of forming a multi-layer IC structure. The method includes forming a BEOL layer having a BEOL layer topography. An etch-stop layer is formed over the BEOL layer topography. The BEOL layer includes a first set of functional elements having a first pattern density, along with a second set of functional elements having a second pattern density that is less than the first pattern density. A metal is formed over the etch-stop layer. A first planarization operation is applied to remove a first portion of the metal. The etch-stop layer is used to stop the first planarization operation. A second planarization operation is applied to remove the etch-stop layer and a second portion of the metal.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a three-dimensional view of a portion of an IC wafer that incorporates aspects of the invention; and

FIGS. 2-7 depict cross-sectional views of a portion of the IC wafer shown in FIG. 1, taken along line A-A, after fabrication operations for forming a planarized dielectric layer in accordance with embodiments of the invention, in which:

FIG. 2 depicts a cross-sectional view of a portion of the IC wafer after fabrication operations in accordance with embodiments of the invention;

FIG. 3 depicts a cross-sectional view of a portion of the IC wafer after fabrication operations in accordance with embodiments of the invention;

FIG. 4 depicts a cross-sectional view of a portion of the IC wafer after fabrication operations in accordance with embodiments of the invention;

FIG. 5 depicts a cross-sectional view of a portion of the IC wafer after fabrication operations in accordance with embodiments of the invention;

FIG. 6 depicts a cross-sectional view of a portion of the IC wafer after fabrication operations in accordance with embodiments of the invention; and

FIG. 7 depicts a cross-sectional view of a portion of the IC wafer after fabrication operations in accordance with embodiments of the invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two- or three-digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, semiconductor devices are used in a variety of electronic applications. ICs are typically formed from various circuit configurations of semiconductor devices (e.g., transistors, capacitors, resistors, etc.) and conductive interconnect layers (known as metallization layers) formed on semiconductor wafers. Alternatively, semiconductor devices can be formed as monolithic devices, e.g., discrete devices. Semiconductor devices and conductive interconnect layers are formed on semiconductor wafers by depositing many types of thin films of material over the semiconductor wafers, patterning the thin films, doping selective regions of the semiconductor wafers, etc.

In contemporary semiconductor fabrication processes, a large number of semiconductor devices and conductive interconnect layers are fabricated. More specifically, during the first portion of chip-making (i.e., the FEOL stage), the individual components (transistors, capacitors, etc.) are fabricated on the wafer. The MOL stage follows the FEOL stage and typically includes process flows for forming the contacts and other structures that communicatively couple to active regions (e.g., gate, source, and drain) of the device element. In the BEOL stage, these device elements are connected to each other through a network of interconnect structures to distribute signals, as well as power and ground. The conductive interconnect layers formed during the BEOL stage serve as a network of pathways that transport signals throughout an IC, thereby connecting circuit components of the IC into a functioning whole and to the outside world. Because there typically isn't enough room on the chip surface to create all of the necessary connections in a single layer, chip manufacturers build vertical levels of interconnects. While simpler ICs can have just a few metallization layers, complex ICs can have ten or more layers of wiring.

Insulating dielectric materials are used throughout the layers of an IC to perform a variety of functions including stabilizing the IC structure and providing electrical isolation of the IC elements. Additionally, in order to provide a parasitic resistance and capacitance (RC) level that is sufficiently low to support high signal speed applications, regions of the BEOL dielectric material can be formed from low-k and/or ultra-low-k (ULK) dielectric materials having a dielectric constant of less than silicon dioxide, and the interconnect structures (e.g., wire lines and vias) can be formed from copper-containing material. In general, a low-k dielectric generally has a k value that is less than about 4, and a ULK dielectric generally has a k value that is less than about 2.5.

However, there are difficulties with integrating low-k/ULK dielectric materials with functional elements in the dielectric layers of an IC. For example, it is a challenge to planarize a low-k/ULK BEOL layer with functional elements formed therein in a well-controlled manner that achieves uniform post-planarization height dimensions in the low-k/ULK BEOL layers. Non-uniform interconnect/dielectric heights result in different resistance levels across the BEOL layer interconnect structures, which results in undesirable resistance (R) variability. The RC variability that results from height/spacing variability in the BEOL layer negatively impacts IC performance, particularly for high-speed applications.

Turning now to an overview of the aspects of the invention, embodiments of the invention address the variability problems associated with known methods of planarizing low-k/ULK BEOL layers by utilizing, in accordance with aspects of the invention, a novel dielectric layer planarization process that incorporates the formation of a metal overburden and an etch-stop layer. In some embodiments of the invention, the etch-stop layer can be a liner layer, a barrier layer, and/or a combined liner/barrier layer. In some embodiments of the invention, the etch-stop layer is selected from a group consisting of a liner; a barrier; and the liner and the barrier. In embodiments of the invention, the metal overburden and the etch-stop layer are sacrificial in that they are consumed during the novel dielectric planarization process.

In accordance with embodiments of the invention, the dielectric layer includes a dense region and a sparse region. The dense region and the sparse region each includes functional elements that are spaced apart from one another. In the dense region, a predetermined number (X) of the functional elements are provided and positioned within the dense region such that there is an average distance or space (Y) between the functional elements. In the sparse region, a predetermined number (X′) of the functional elements are provided and positioned within the dense region such that there is an average distance or space (Y′) between the functional elements. In accordance with aspects of the invention, there are fewer functional elements in the sparse region than in the dense region; and the functional elements in the sparse region are spaced further apart than the functional elements in the dense region. Accordingly, in embodiments of the invention, X is greater than X′, and Y is less than Y′. In general, the element density of a section of a layer is the fractional volume of the section of the layer (e.g., the dense region, or the sparse region) that is occupied by functional elements (e.g., memory elements). In some aspects of the invention, the difference between the dense region and the sparse region can be represented by the element density of the dense region in comparison with the element density of the sparse region. In embodiments of the invention, the element density of the dense region is greater than the element density of the sparse region. In some embodiments of the invention, the element density of the dense region is greater than about 50%; and the element density of the sparse region is greater than zero percent and less than about 5%.

In some embodiments of the invention, the functional elements are magnetic tunnel junction (MTJ) pillars configured to include, for example, an MTJ stack, a top electrode, a bottom electrode, a hard mask, and the like. In general, the MTJ stack is the main storage element of MRAM, and multiple instances of the MTJ stack can be arranged within the MRAM in a dense configuration (e.g., the dense region of the dielectric layer) and/or a sparse configuration (e.g., the sparse region of the dielectric layer). A basic MTJ stack includes a free layer and a fixed/reference layer, each of which includes a magnetic material layer. The free and reference layers are separated by a non-magnetic insulating tunnel barrier. The free layer and the reference layer are magnetically de-coupled by the tunnel barrier. The free layer has a variable magnetization direction, and the reference layer has an invariable magnetization direction. A wide variety of layers and elements (e.g., a cap, multiple free/reference layers, etc.) can be included in an MTJ stack. The MTJ stack stores information by switching the magnetization state of the free layer. When the free layer's magnetization direction is parallel to the reference layer's magnetization direction, the MTJ stack is in a low resistance state. Conversely, when the free layer's magnetization direction is anti-parallel to the reference layer's magnetization direction, the MTJ stack is in a high resistance state. The difference in resistance of the MTJ stack can be used to indicate a logical “1” or “0,” thereby storing a bit of information. The tunneling magnetoresistance (TMR or MR) of an MTJ stack determines the difference in resistance between the high and low resistance states. A relatively high difference between the high and low resistance states facilitates read operations in the MRAM.

In some embodiments of the invention, the functional elements are a network of conductive interconnect structures (e.g., lines (or wires) and metal-filled vias) that distribute signals, power, and ground throughout the IC. Because there typically isn't enough room on the chip surface to create all of the necessary connections in a single layer, chip manufacturers build vertical levels of interconnects. While simpler ICs can have just a few metallization layers, complex ICs can have ten or more layers of interconnects. The interconnect structures can be local interconnects and/or global interconnects. Local interconnects are physically close to FEOL-stage components (e.g., transistors and the like) so need to be small because they attach/join to the components that are themselves very small and often closely packed together. Thus, local interconnects are usually thin and short in length. Global interconnects are higher up in the IC layer structure and travel between different blocks of the circuit. Thus, global interconnects are typically thick, long, and more widely separated than local interconnects.

In some embodiments of the invention, the functional elements can be a combination of MTJ pillars/stacks and interconnects. In some embodiments of the invention, the functional elements can be MTJ pillars/stacks embedded in an interconnect network of the IC.

In embodiments of the invention, the dielectric layer is formed from a gap-fill dielectric material. In embodiments of the invention, the dielectric layer can be formed by depositing the gap-fill dielectric material over the functional elements such that the functional elements are embedded within the gap-fill dielectric material. In aspects of the invention, the functional elements are positioned such that a top surface of the dielectric layer has a particular topography that is determined by the spacing between the functional elements. More specifically, the topography is higher for portions of the top surface that are above a functional element; and the topography is lower for portions of the top surface are not above a functional element (i.e., above a space between the functional elements). The higher and lower portions of the topography result in the top surface topography of the dielectric layer defining a series of trenches (i.e., the portions of the top surface that are not above a functional element). In embodiments of the invention, because there are more functional elements in the dense region than the sparse region, the trenches in the dense region are more numerous and less wide (or narrower) than the trenches in the sparse region.

The increasing number of BEOL layers requires a highly planarized surface on every layer. Accordingly, the above-described top surface topography of the dielectric layer must be planarized before additional layers can be formed thereon. However, the presence of the top surface topography of the dielectric layer, and particularly the relatively wide trenches in the sparse region, make it extremely difficult to apply a planarization process such as CMP directly on the top surface topography of the dielectric layer.

Embodiments of the invention provide a novel dielectric layer planarization process configured and arranged to planarize a dielectric layer having a top surface topography, including specifically the above-described top surface topography having narrow trenches in a dense region of the dielectric layer and wide trenches in a sparse region of the dielectric layer. In embodiments of the invention, the dielectric layer planarization process includes the formation of an etch-stop layer and a metal overburden. In accordance with aspects of the invention, the etch-stop layer and the metal overburden are sacrificial in that they are consumed during the novel dielectric planarization process. In some embodiments of the invention, the etch-stop layer is conformally deposited over the top surface topography of the dielectric layer such that the etch-stop layer is present on the higher surfaces of the top surface topography and within the trenches of the top surface topography. To provide a surface that is more conducive to planarization than the top surface topography, a metal is deposited over the etch-stop layer such that metal includes a first portion that is within the trenches and a second portion that extends above the trenches. The second portion of the metal is a metal overburden. Unlike the above-described etch-stop layer, the metal overburden is sufficiently thick that its top surface does not track the dielectric layer's top surface topography. In accordance with aspects of the invention, the metal overburden provides a top surface that is more easily planarized than the top surface topography of the dielectric layer.

In embodiments of the invention, the novel dielectric planarization process applies two planarization processes to the metal, the etch-stop layer, and the dielectric layer. More specifically, a first planarization process is applied that removes the second portion (i.e., the overburden) of the metal, planarizes the first portion of the metal, and stops on the etch-stop layer, which is over the highest portions of the top surface topography of the dielectric layer. The first planarization process can be a CMP that uses an endpoint signal to detect a change from planarizing the metal to planarizing the etch-stop layer. The endpoint signal controls the CMP tool to stop the CMP operations at the etch-stop layer. After the first planarization process, the second portion of the metal has been removed and a substantially planar surface has been formed that includes exposed surfaces of the etch-stop layer and exposed surfaces of the first portion of the metal. A second planarization process is applied to the above-described substantially planar surface until the etch-stop layer and the first portion of the metal are removed, thereby removing the top surface topography of the dielectric layer and forming a planarized top surface of the dielectric layer. In embodiments of the invention, the second planarization process is a timed planarization operation that is selective to the etch-stop layer, the first portion of the metal, and/or the dielectric layer.

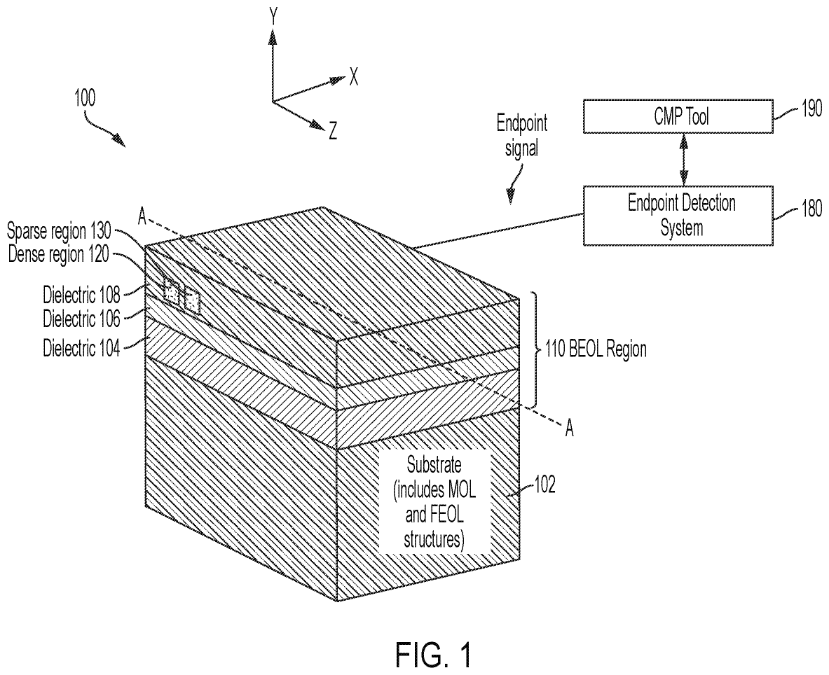

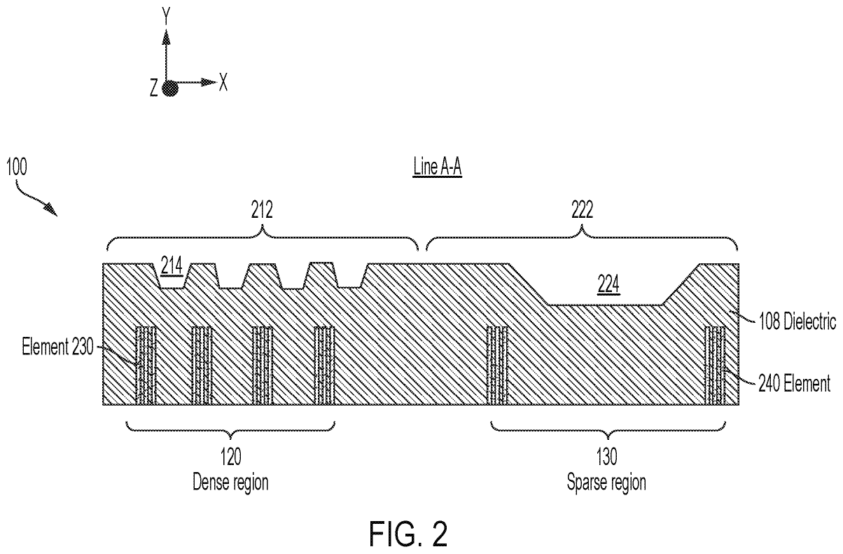

Turning now to a more detailed description of aspects of the present invention, FIG. 1 depicts a portion of an IC wafer 100 in accordance with aspects of the invention. The IC wafer 100 includes a substrate 102 having MOL and FEOL structures (not shown separately) formed in MOL and FEOL regions (not shown separately) of the substrate 102. A BEOL region 110 having multiple layers is formed over the substrate 102. The BEOL region 110 includes a BEOL dielectric layer 104, a BEOL dielectric layer 106, and a BEOL dielectric layer 108, configured and arranged as shown. Although three BEOL dielectric layers 104, 106, 108 are shown in FIG. 1, the BEOL region 110 can be provided with any number of dielectric layers. The BEOL dielectric layer 108 is formed from a low-k (or ULK) dielectric material having a dense region 120 and a sparse region 130. The dense region 120 includes functional elements 230 (shown in FIG. 2), and the sparse region 130 includes functional elements 240 (shown in FIG. 2). Although one instance of the dense region 120 and one instance of the sparse region 130 are shown in FIG. 1, any number of dense regions 120 and sparse regions 130 can be provided. In accordance with aspects of the invention, some or all of the BEOL dielectric layers 104, 106, 108 in the BEOL region 110 can be provided with the dense regions 120 and the sparse regions 130. The functional elements 230, 240 can be any suitable functional element of an IC, including, for example MTJ stacks/pillar and/or interconnect structures.

Insulating dielectric materials are used throughout the layers of the IC wafer 100 (best shown in FIG. 1) to perform a variety of functions including stabilizing the IC wafer 100 and providing electrical isolation of the IC devices and interconnect structures formed in the IC wafer 100. For example, the functional elements 230, 240 (shown in FIG. 2) in the BEOL dielectric layer 108 of the IC wafer 100 are isolated by BEOL dielectric layers 104, 106, 108 to prevent the functional elements 230, 240 from creating a short circuit with other metal layers/structures in the IC wafer 100. Additionally, in order to provide a parasitic resistance and capacitance (RC) level that is sufficiently low to support high signal speed applications, layers of the BEOL region 110 can be formed from low-k and/or ULK dielectric materials having a dielectric constant of less than silicon dioxide, and the interconnect structures (e.g., wire lines and vias) can be formed from copper-containing material. The RC product is a measure of the time delay introduced into the circuitry by the interconnect structures in the BEOL dielectric layers 108, 106, 106. A low-k dielectric generally has a k value that is less than about 4, and a ULK dielectric generally has a k value that is less than about 2.5. Suitable dielectric low-k/ULK materials for reducing interconnect capacitance in the BEOL region 110 include, for example, fluorine-doped silicon dioxide, porous organosilicate glass material (e.g., SiCOH), porous silicon dioxide, and organic polymeric materials such as polyimide, polynorbornenes, benzocyclobutene, and hydrogen sisesquioxane, and the like.

An endpoint detection system 180 is communicatively coupled to the IC wafer 100 (including the functional elements 230, 240 shown in FIG. 2) to detect an endpoint signal that indicates that the CMP tool 190 has transitioned (or is transitioning) from planarizing one type of material to another type of material (i.e., the material that generates the endpoint signal). Upon detecting the endpoint signal, the endpoint detection system 180 controls the CMP tool 190 to stop planarization operations.

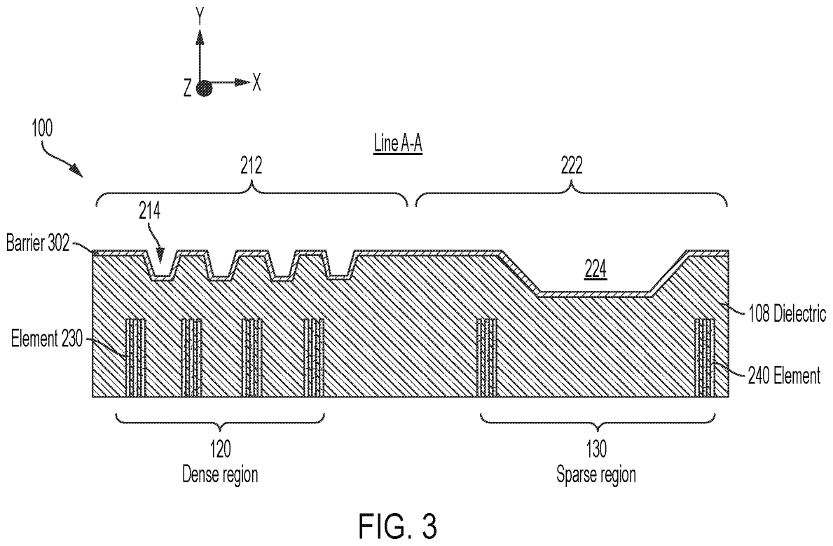

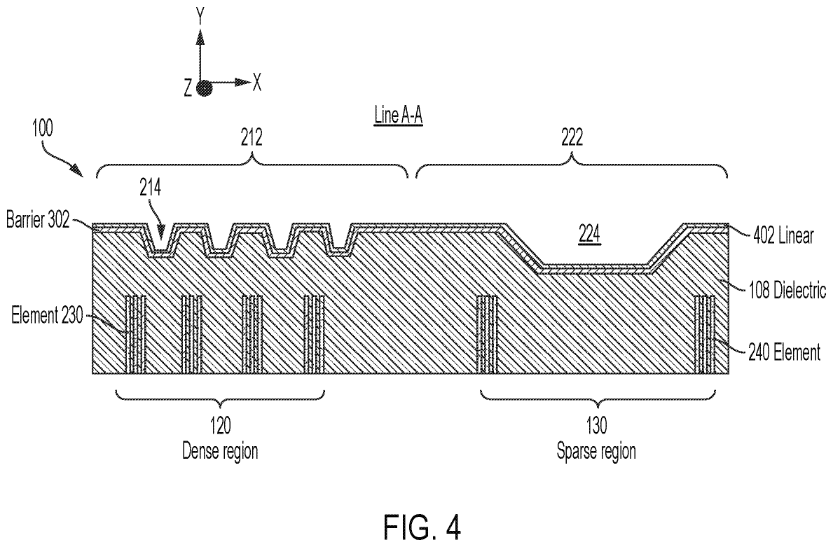

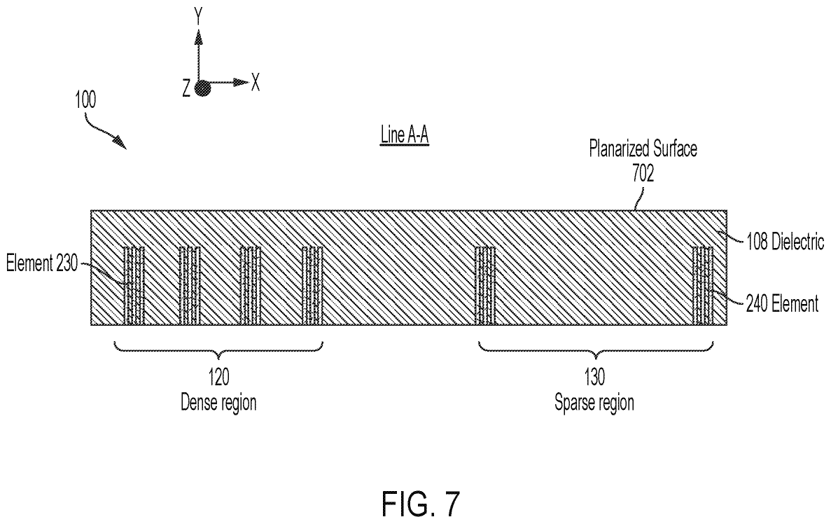

In accordance with embodiments of the invention, the BEOL dielectric layer 108 having the dense region 120 and the sparse region 130 has been planarized using the novel dielectric layer planarization process depicted in FIGS. 2-7. As described in greater detail below, in embodiments of the invention, after a non-planarized version of BEOL dielectric layer 108 is formed, the novel dielectric layer planarization process deposits an etch-stop layer (e.g., barrier layer 302 shown in FIG. 3; and liner layer 402 shown in FIG. 4) and a metal 502 (shown in FIG. 3) over the non-planarized version of BEOL dielectric layer 108; and two planarization processes are applied to the metal 502, the etch-stop layer 302, 402, and the BEOL dielectric layer 108. The first planarization process planarizes the metal 502 and stops on the etch-stop layer 302, 402. The first planarization process can be a CMP that uses the endpoint detection system 180 to detect an endpoint signal that indicates that the CMP tool 190 has gone from planarizing the metal 502 to planarizing the etch-stop layer 302, 402. Upon detecting the endpoint signal, the endpoint detection system 180 controls the CMP tool 190 to stop the first planarization process at the etch-stop layer 302, 402. A second planarization process is applied to remove the remaining portions of the etch-stop layer 302, 402, the metal 502, and portions of the BEOL dielectric layer 108, thereby forming a planarized top surface 702 (shown in FIG. 7) of the BEOL dielectric layer 108. In embodiments of the invention, the second planarization process is a timed planarization operation that is selective to the etch-stop layer 302, 402, the metal 502, and/or the BEOL dielectric layer 108.

FIGS. 2-7 depict cross-sectional views of a portion of the IC wafer 100 shown in FIG. 1, taken along line A-A, after fabrication operations for forming the planarized BEOL dielectric layer 108 in accordance with embodiments of the invention. As shown in FIGS. 2-7, the BEOL dielectric layer 108 includes the dense region 120 and the sparse region 130 in accordance with aspects of the invention. As shown in FIG. 2, the IC wafer 100 is depicted after an initial set of fabrication operations have been performed to form the functional elements 230 in the dense region 120; form the functional elements 240 in the sparse region 130; and deposit a gap-fill dielectric that forms the non-planarized version of the BEOL dielectric layer 108. In embodiments of the invention, the functional elements 230, 240 can be MTJ stacks/pillars; interconnects; and/or a combination of MTJ stacks/pillars and interconnects. In general, the number of functional elements 230 in the dense region 120 is greater than the number of functional elements 240 in the sparse region 130. Additionally, the spacing between the functional elements 230 is less than the spacing between the functional elements 240. A variety of well-known IC fabrication operations are suitable for forming the IC wafer 100 to the fabrication stage shown in FIG. 2. Accordingly, in the interest of brevity, such well-known fabrication operations are either omitted or described and illustrated at a high level.

In some embodiments of the invention, the locations and spacings of the functional elements 230 are configured to define or determine a topography 212 of a top surface of the BEOL dielectric layer 108 in the dense region 120; and the locations and spacings of the functional elements 240 are configured to define or determine a topography 222 of the top surface of the BEOL dielectric layer 108 in the sparse region 130. More specifically, the topography 212, 222 is higher for portions of the top surface of the BEOL dielectric layer 108 that are above one of the functional elements 230, 240; and the topography 212, 222 is lower for portions of the top surface of the BEOL dielectric layer 108 that are not above one of the functional elements 230, 240. The higher and lower portions of the topography 212, 222 define a series of trenches 214, 224 (i.e., the portions of the top surface of the BEOL layer 108 that are not above one of the functional elements 230, 240). In embodiments of the invention, because there are more functional elements 230 in the dense region 120 than the functional elements 240 in the sparse region 130, the trenches 214 in the dense region 120 are more numerous and less wide (or narrower) than the trenches 224 in the sparse region 130.

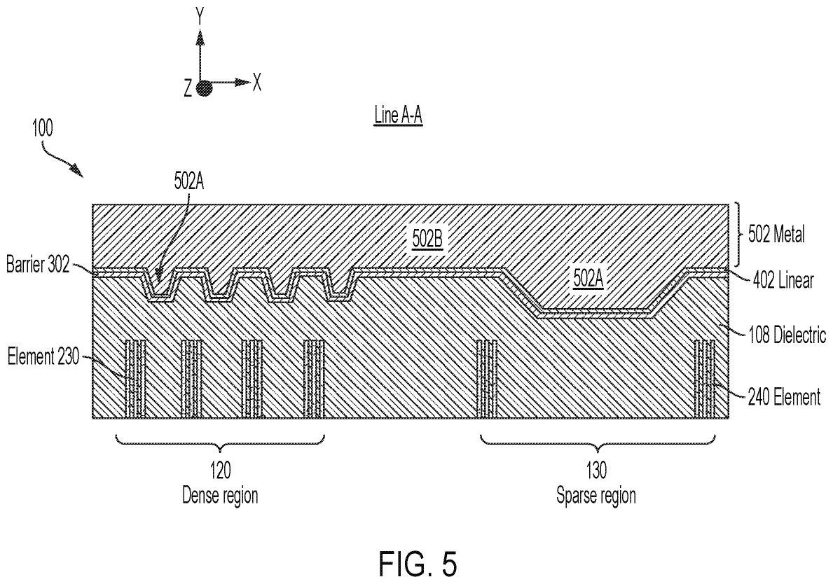

In FIG. 3, known fabrication operations (e.g., atomic layer deposition (ALD)) have been used to conformally deposit a barrier layer 302 over the BEOL dielectric layer 108. In embodiments of the invention, the barrier layer 302 can be formed from TaN and is configured to prevent diffusion of the metals in the liner layer 302 (shown in FIG. 4) and the metal 502 (shown in FIG. 5) into the BEOL dielectric layer 108.

In FIG. 4, known fabrication operations (e.g., ALD) have been used to conformally deposit a liner layer 402 over the BEOL dielectric layer 108. In embodiments of the invention, the liner layer 402 can be formed from Ru or Co and is configured to improve adhesion between the metal 502 (shown in FIG. 5), the barrier layer 302, and the BEOL dielectric layer 108. In accordance with embodiments of the invention, the liner layer 402 functions as an etch-stop.

In FIG. 5, known fabrication operations have been used to form a metal 502 over the liner layer 302. The metal 502 includes first metal portions 502A positioned within the trenches 214, 224, along with a second metal portion 502B over the first metal portions 502A. In aspects of the invention, the second metal portion 502B of the metal 502 is a metal overburden. The metal 502 can be formed by depositing a thin sputtered metal (e.g., Cu) seed layer (not shown separately) over the liner layer 402. The seed layer enables the electrochemical deposition (ECD) of the metal 502 at a sufficient thickness to fill the trenches 214, 224 and create the second metal portion 502B of the metal 502. In some embodiments of the invention, a reflow operation is applied to the metal 502 to ensure that the metal 502 fills in all of the space within the trenches 214, 224.

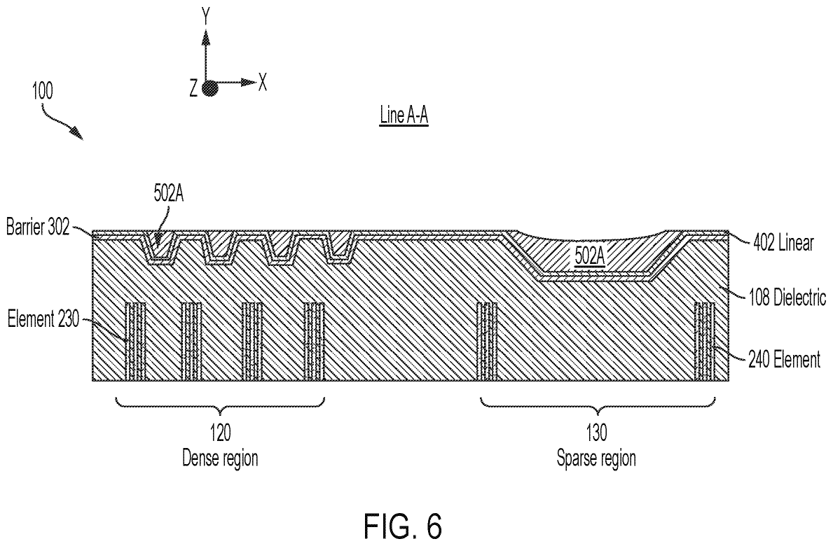

In FIG. 6, a first planarization process is applied to the metal 502 to remove the second metal portion 502B of the metal 502 and stop on the barrier/liner 302, 402. The first planarization process can be a CMP that uses an endpoint signal to detect a change from planarizing the metal 502 to planarizing the barrier/liner 302, 402. The endpoint signal is detected by the endpoint detection system 180, and in response to detecting the endpoint signal the endpoint detection system 180 controls the CMP tool 190 to stop the CMP operations at the liner layer 302. After the first planarization process, the relatively large width of the first metal portion 502A of the metal 502 can result in post-planarization dishing on the surface of the first metal portion 502A of the metal 502. The dishing, if it occurs, can be removed using a CMP buff operation. After the first planarization process and any necessary buffing, a substantially planar surface is formed by exposed portions of the liner layer 302 and top surfaces of the first metal portions 502A of the metal 502.

In FIG. 7, a second planarization process is applied to the substantially planar surface formed by the exposed portions of the liner layer 302 and top surfaces of the first metal portions 502A of the metal 502 shown in FIG. 6. The second planarization process completely removes the remaining portions of the etch-stop layer 302, 402, the first metal portions 502A, and portions of the BEOL dielectric layer 108, thereby forming a planarized top surface 702 of the BEOL dielectric layer 108. In embodiments of the invention, the second planarization process is a timed planarization operation that is selective to the liner/barrier layers 302, 402, the metal 502, and/or the BEOL dielectric layer 108.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

“Planarization” and “planarize” as used herein refer to a material removal process that employs at least mechanical forces, such as frictional media, to produce a substantially two-dimensional surface. A planarization process can include CMP or grinding. CMP is a material removal process that uses both chemical reactions and mechanical forces to remove material and planarize a surface.

The phrase “selective to,” such as, for example, an etchant that is “selective to a first element and non-selective to a second element,” means that the etchant etches the first element, and the second element can act as an etch stop to the etchant.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), CMP, and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of forming portions of a multi-layered integrated circuit (IC), the method comprising:
forming a dielectric layer having a top surface topography;
forming an etch-stop layer over the top surface topography;
forming a metal over the etch-stop layer;
applying a first planarization operation to remove a first portion of the metal;
using the etch-stop layer to stop the first planarization operation; and
applying a second planarization operation to remove the etch-stop layer and a second portion of the metal.

2. The method of claim 1 further comprising applying a reflow operation to the metal.

3. The method of claim 1, wherein applying the second planarization operation completely removes the metal.

4. The method of claim 1, wherein the second planarization operation comprises a timed planarization operation.

5. The method of claim 1, wherein the top surface topography comprises:
a first set of trenches; and
a second trench;
wherein a width of each of the first set of trenches is less than a width of the second trench.

6. The method of claim 5, wherein the top surface topography is determined by functional elements formed in the dielectric layer.

7. The method of claim 6, wherein the functional elements comprise magnetic tunnel junction (MTJ) pillars.

8. The method of claim 6, wherein the functional elements comprise interconnect structures.

9. The method of claim 5, wherein:
the first portion of the metal comprises a metal overburden above the etch-stop layer; and
the second portion of the metal is within the first set of trenches and the second trench.

10. The method of claim 9, wherein the dielectric layer comprises a low-k dielectric in a back-end-of-line (BEOL) region of the multi-layered IC.

11. A method of forming portions of a multi-layered integrated circuit (IC), the method comprising:
forming a back-end-of-line (BEOL) layer having a BEOL layer topography;
wherein the BEOL layer comprises:
a first set of functional elements having a first pattern density; and
a second set of functional elements having a second pattern density that is less than the first pattern density;
forming an etch-stop layer over the BEOL layer topography;
forming a metal over the etch-stop layer;
applying a first planarization operation to remove a first portion of the metal;
using the etch-stop layer to stop the first planarization operation; and
applying a second planarization operation to remove the etch-stop layer and a second portion of the metal.

12. The method of claim 11 further comprising applying a reflow operation to the metal.

13. The method of claim 11, wherein applying the second planarization operation completely removes the metal.

14. The method of claim 11, wherein the second planarization operation comprises a timed planarization operation that is selective to the etch-stop layer, the second portion of the metal, and the BEOL layer.

15. The method of claim 11, wherein the BEOL layer topography comprises:
a first set of trenches; and
a second trench;
wherein a width of each of the first set of trenches is less than a width of the second trench.

16. The method of claim 15, wherein the BEOL layer topography is determined by the first set of functional elements and the second set of functional elements.

17. The method of claim 16, wherein the first set of functional elements and the second set of functional elements comprise magnetic tunnel junction (MTJ) pillars.

18. The method of claim 16, wherein the first set of functional elements and the second set of functional elements comprise interconnect structures.

19. The method of claim 15, wherein:
the first portion of the metal comprises a metal overburden above the etch-stop layer; and
the second portion of the metal is within the first set of trenches and the second trench.

20. The method of claim 19, wherein the etch-stop layer is selected from a group consisting of:
a liner;
a barrier; and
the liner and the barrier.
